(19) United States
(12) Patent Application Publication
(10) Pub. No.: US 2011/0266043 A1
(43) Pub. Date: Nov. 3, 2011

(54) SUBSTRATE

(75) Inventors: Takeshi UESUGI, Tokyo (JP); Daisuke Fujisaki, Tokyo (JP)

(73) Assignee: TDK-Lambda Corporation, Chuo-ku (JP)

(21) Appl. No.: 12/986,458

(22) Filed: Jan. 7, 2011

(30) Foreign Application Priority Data
Jan. 14, 2010 (JP) 006082/2010

(51) Int. Cl. H05K 1/11

(52) U.S. Cl. 174/261

(57) ABSTRACT

It is an object of the invention to provide a substrate which allows visual confirmation of the joint state and improvement of reliability of the joint between the components and the substrate to be mounted. The substrate is configured to mount a component having a planer terminal and include a land subjected to solder joint with respect to the terminal of the component.

A substrate includes notched portions formed by notching parts of the lands in the direction away from an end surface forming the space. The each land on the substrate includes a first land formed on the substrate and a second land formed of an end surface of the notched portion in the direction of thickness of the substrate. Therefore, visibility of parts of terminals of components is secured utilizing penetration of the notched portions at the time of soldering, so that the joint state of soldering can be visually confirmed.

### BACKGROUND OF THE INVENTION

1. Field of the Invention

The present invention relates to a substrate for mounting an electronic component or the like and, more specifically, to a substrate for surface-mounting a component having a planer terminal on the surface thereof.

2. Description of the Related art

In a substrate which constitutes an electronic circuit or the like, an electronic component having planer terminals and lands formed on the substrate are brought into surface contact with each other, so that solder joint is achieved. For example, a transformer or the like configured to rise and drop of voltage is mounted on the substrate of a circuit which controls a power source. The transformer can be joined to the lands provided on a front surface of the substrate, and a planar transformer having a relatively low height is used. Planer transformers are formed by forming a pattern which serves as a coil on a printed board, laminating a plurality of such printed boards, and forming a magnetic circuit by surrounding a center and an outer periphery of a laminated printed board by a magnetic body such as a ferrite core or the like. The transformer is provided with a primary-side terminal and a secondary-side terminal for external connections. The primary-side terminal and the secondary-side terminal are joined to lands on the substrates by soldering via a terminal formed into a planar shape provided in the periphery of a lower surface of the printed board of the transformer as in Patent Document 1. There is also a configuration in which a terminal is provided so as to extend to an outer periphery of the transformer body as in Patent Document 2. In order to mount the transformers as described above on the substrate, it is necessary to provide a land having a surface area larger than the terminal of the transformer on the side of the substrate.

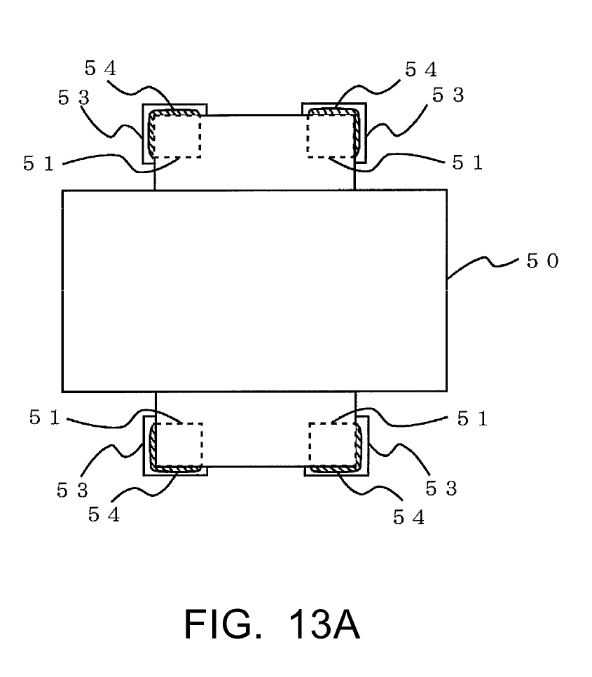

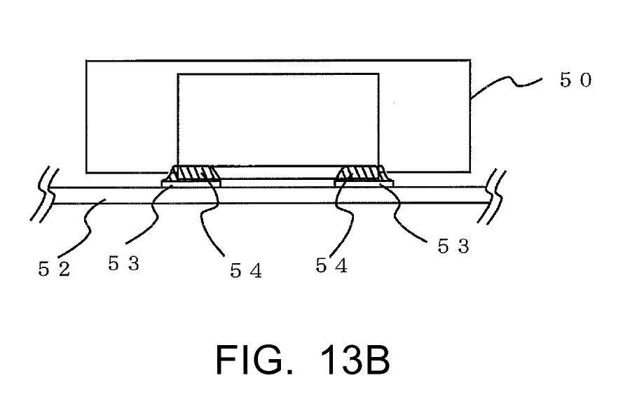

Referring now to FIGS. 13A and 13B, solder joint to be performed when mounting the transformer on the substrate will be described below. FIG. 13A is a plan view of a transformer mounted on a substrate showing a state of solder joint between the terminal of the transformer and the land on the substrate. FIG. 13B is a front view of the transformer mounted on the substrate, also showing the state of solder joint between the terminal of the transformer and the land on the substrate. As described above, the lands each having a surface area larger than a planer terminal of the transformer are provided on the side of the substrate. The reason is that terminals 51 of the transformer 50 are hidden as shown by broken lines when joining the planer terminals 51 located on a lower surface of the transformer 50 and lands 53 on a substrate 52 as shown in FIG. 13A and hence the joint state of solders 54 cannot be confirmed. Therefore, as shown in FIGS. 13A and 13B, portions of the lands 53 on the substrate 52 which are not in contact with the terminals 51 of the transformer 50 and periphery of the lower surface of the transformer 50 are also provided with the solders 54 shown with hatching.

When a terminal is provided so as to extend to the outer periphery of the transformer, the solder is provided also in the periphery of the terminal of transformer using a land on the substrate which is not in direct contact with the terminal of the transformer.

As an alternative of the terminal extending to the outside of the transformer body, a transformer having pins extending vertically from through holes of the printed board and joined at distal ends of the pins to the lands on the substrate by soldering is also known.

### Prior Art Document

### Patent Document

### Patent Document 1: JP-A-3-181191

### Patent Document 2: JP-A-5-291062

### SUMMARY OF THE INVENTION

### Means for Solving the Problem

As described above, in order to achieve the surface mounting of the transformer or the like having the planer terminals to the substrate, it is necessary to provide lands each having a surface area larger than a portion which comes into contact with the terminal of the transformer on the front surface of the substrate. Accordingly, the size of the each land is increased, and hence the substrate is also upsized, which results in cost increase. When using the pins, an operation to mount the pins is necessary, and additional cost for the pins is also required. In contrast, in a case where planer terminals provided on the lower surface of the printed board which forms the transformer, the joined portions are hidden by a component body, and hence the joint state can hardly be visually confirmed. Therefore, a configuration which allows visual confirmation of the joint state and improvement of reliability of the joint between the components to be mounted and the substrate is required.

Accordingly, it is an object of the invention to provide a substrate which ensures solder joint between terminals of components to be mounted and lands on the substrate by causing part of the terminals of the components to be exposed on the lands on the substrate when mounting the components having planer terminals provided on a lower surface or a bottom portion thereof.

### Means for Solving the Problem

In order to achieve the object as described above, there is provided a substrate configured to mount a component having a planer terminal including: a land subjected to solder joint with respect to the terminal of the component, wherein at least part of the land is notched in a direction away from an end surface of the substrate.

Preferably, the substrate according to the invention includes: a space penetrating through the substrate; and a notched portion formed by notching the part of the land in the direction away from the end surface of the substrate which defines the space.

Preferably, the end surface of the notch is plated with a conductive material, and is formed so as to be in a state of conducting with the land on the substrate.

Preferably, the land on the substrate is formed so that part of the terminal of the component is positioned right above the notch.

Preferably, the land on the substrate is made up of the land provided on the substrate and the end surface of the notch in the direction of the thickness of the substrate.

Preferably, a conductive pattern is provided on the substrate on a surface opposite from a surface for mounting the component via the notch.

### Technical Advantages of the Invention

The substrate according to the invention allows soldering in a state in which part of the terminal of the electronic component or the like is exposed on the land of the substrate by notching part of the land in the direction away from the end surface of the substrate, so that the solder joint between the terminal of the component to be mounted and the land on the substrate is ensured.

Also, with the provision of the notches on the lands, the terminals on the lower surface of the member extending from the side surface is exposed on the land of the substrate, and hence is visible, so that reliable solder joint between the terminals of the components and the lands of the substrate is achieved.

In particular, when performing solder joint by inserting an extremity of a soldering iron into the notch, part of the terminal of the component is visible using penetration of the notch, so that accurate soldering can be performed while confirming the state of the solder joint.

Since the lands of the substrate of the invention is made up of the lands provided on the substrate and the end surfaces of the notches in the direction of the thickness of the substrate, the surface area of the solder joint portion between the terminals of the electronic components or the like and the lands of the substrate can be increased, and the amount of solder used for joint can be increased. Accordingly, the lands of the substrate of the invention allow passage of a large current, and hence is suitable for mounting the power conversion components such as a transformer.

Since the substrate of the invention is provided with the notches on the lands, touch up (addition and mending of solder) after the mount of the components can be performed easily via the notches.

The substrate of the invention is provided with the conductive patterns on the surface opposite from the surface for mounting the component via the notch, and hence heat from the terminal of the component is also transferred to the conductive patterns. Therefore, the patterns also functions as a heat-radiating pattern.

The substrate according to the invention includes the space penetrating therethrough for insertion of parts of the component bodies on the substrate, and the notches formed by notching parts of the lands in the direction away from the end surface defining the space of the substrate. Therefore, it is suitable for mounting the component having a terminal on the lower surface of the member extending from the side surface. In other words, since the component is mounted into the space provided in the substrate in a state in which part of the component is penetrated through the substrate, the height of the component from the front surface of the substrate can be kept low. Also, with the provision of the notches on the lands, the terminals on the lower surface of the member extending from the side surface is exposed on the land of the substrate, and hence is visible, so that reliable solder joint between the terminals of the components and the lands of the substrate is achieved.

The planer transformer in the related art is required to form a terminal for mounting the same separately on the substrate, or to prepare a specific terminal base, and hence has a special terminal. Therefore, the substrates are required to have forms corresponding to the forms of the terminals on the respective planer transformers. The substrate of the invention is suitable for mounting the standardized surface-mounting planer transformer, and hence supports the mounting of the power conversion components such as various planer transformers having a planar terminal.

### BRIEF DESCRIPTION OF THE PREFERRED EMBODIMENT

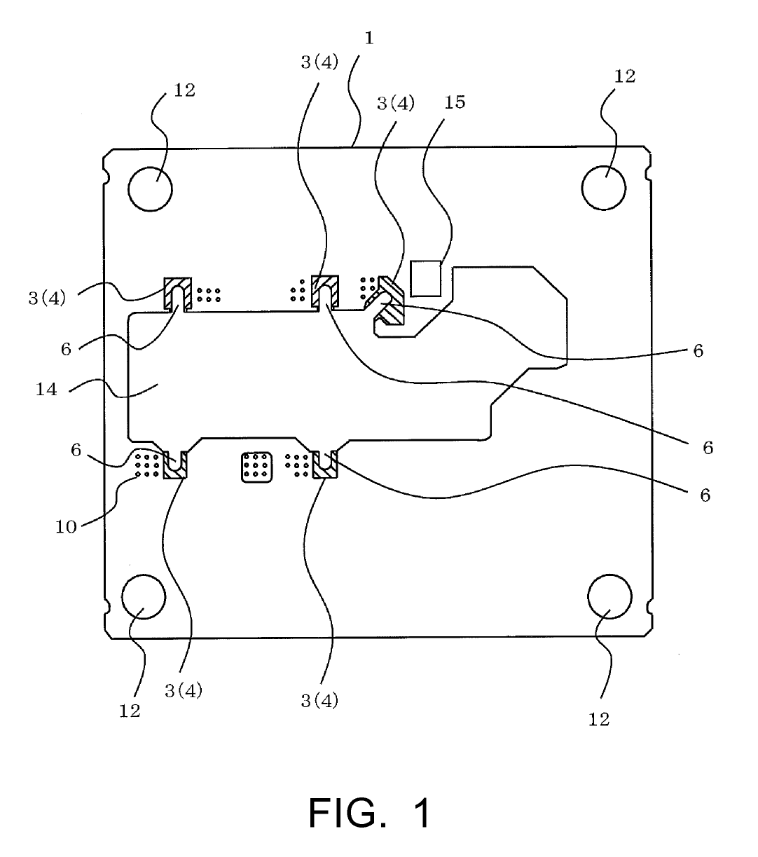

FIG. 1 is a drawing showing a front surface of a substrate according to the invention;

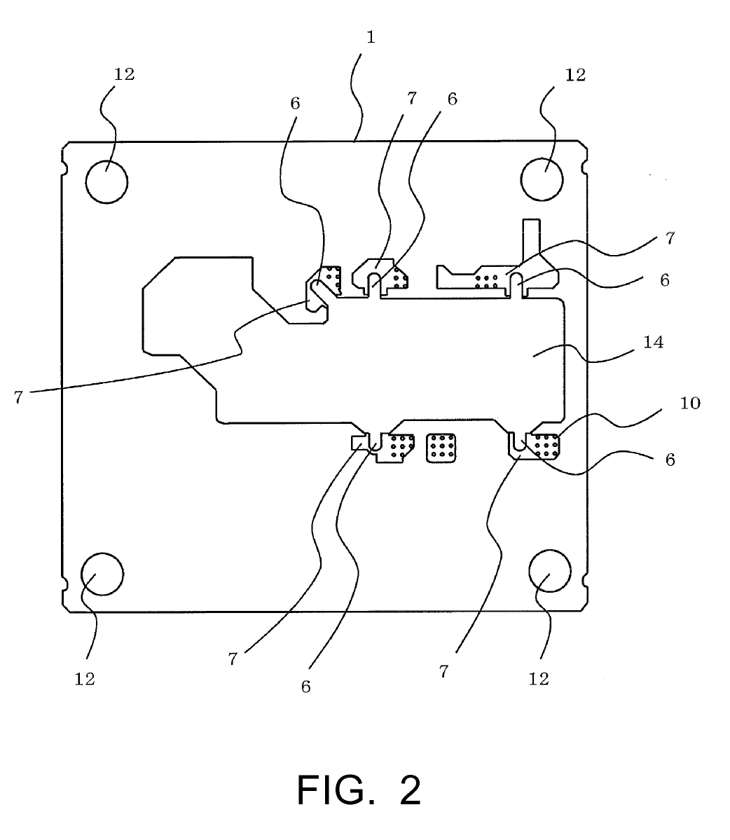

FIG. 2 is a drawing showing a back surface of the substrate according to the invention;

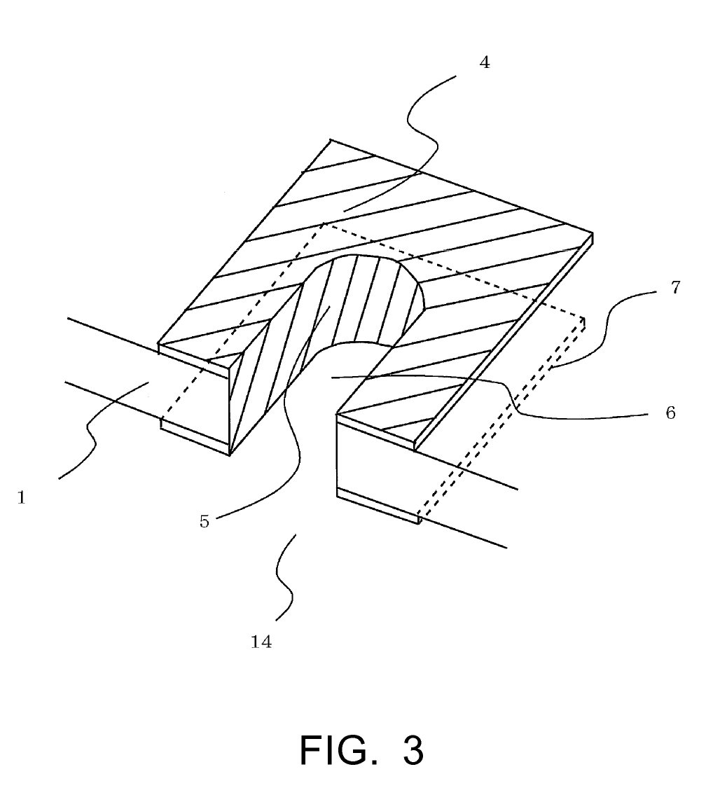

FIG. 3 is an enlarged perspective view showing lands on the substrate according to the invention;

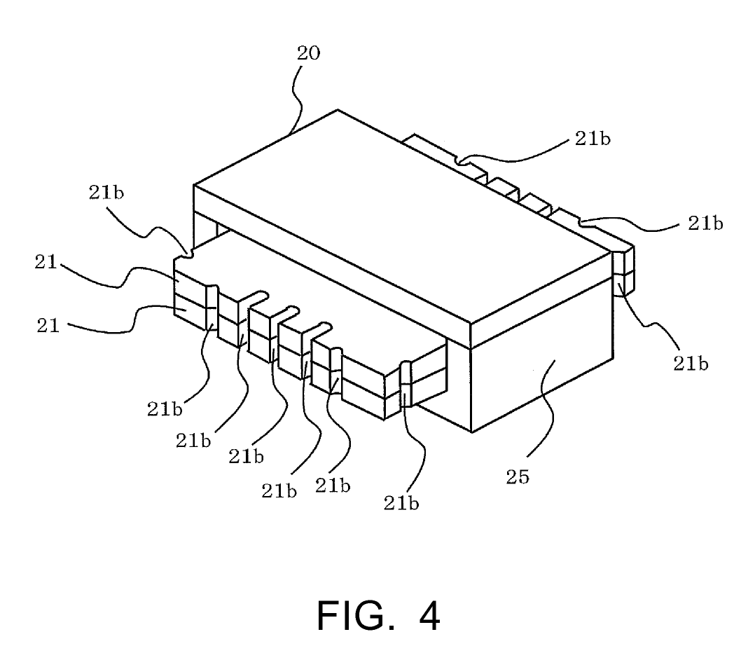

FIG. 4 is a perspective view of a planer transformer to be mounted on the substrate according to the invention;

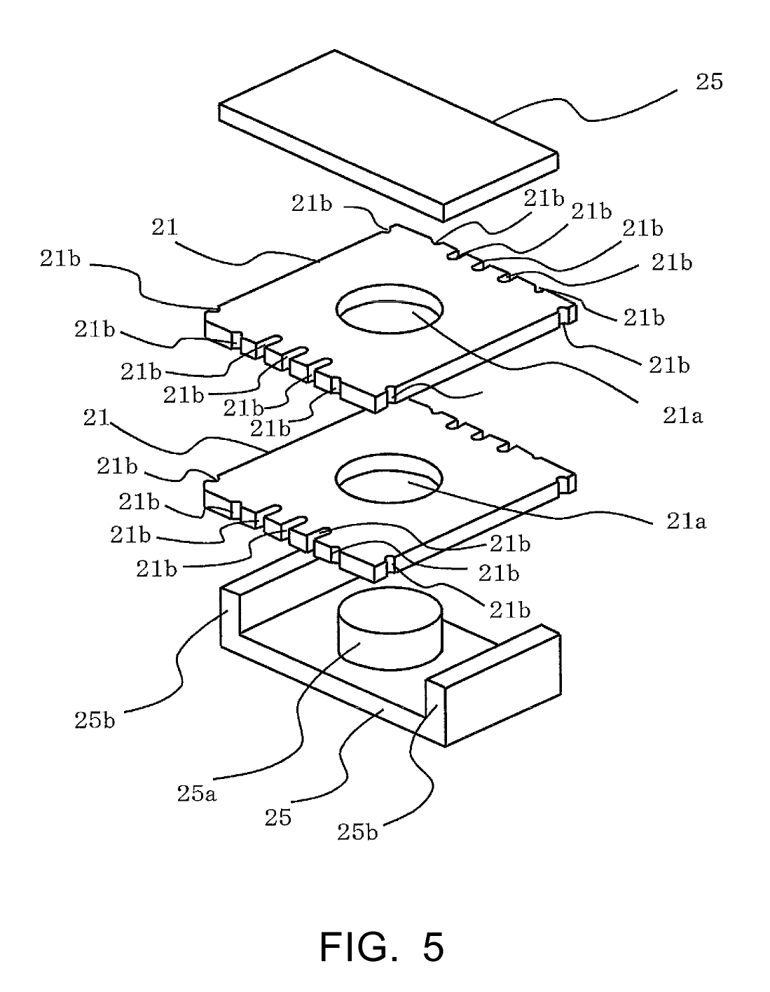

FIG. 5 is a development elevation of the planer transformer;

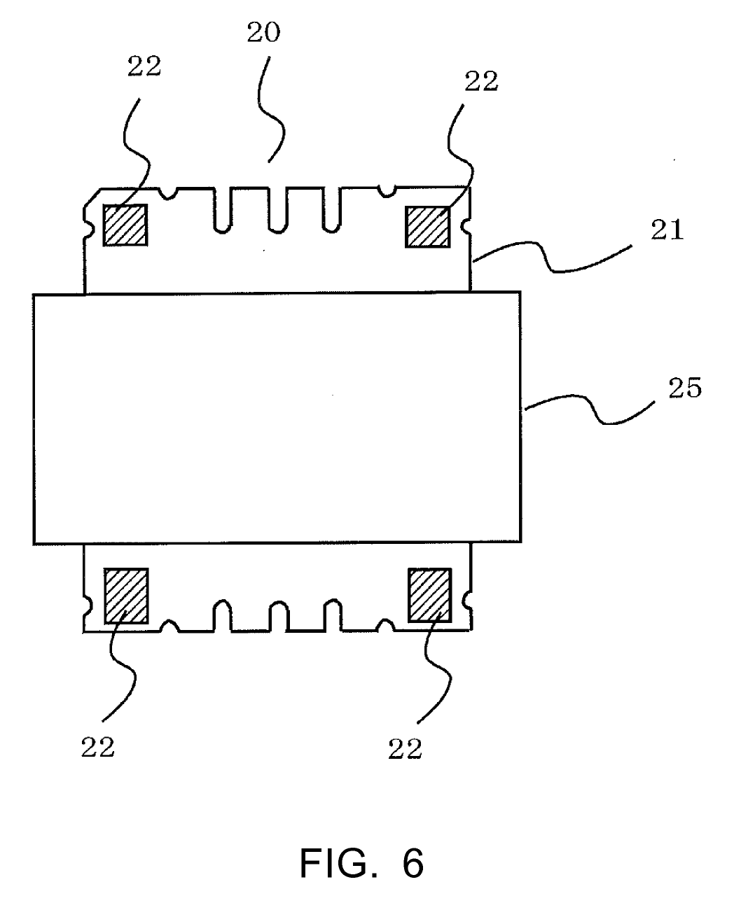

FIG. 6 is a drawing showing positions of terminals when viewing the planer transformer from the backside;

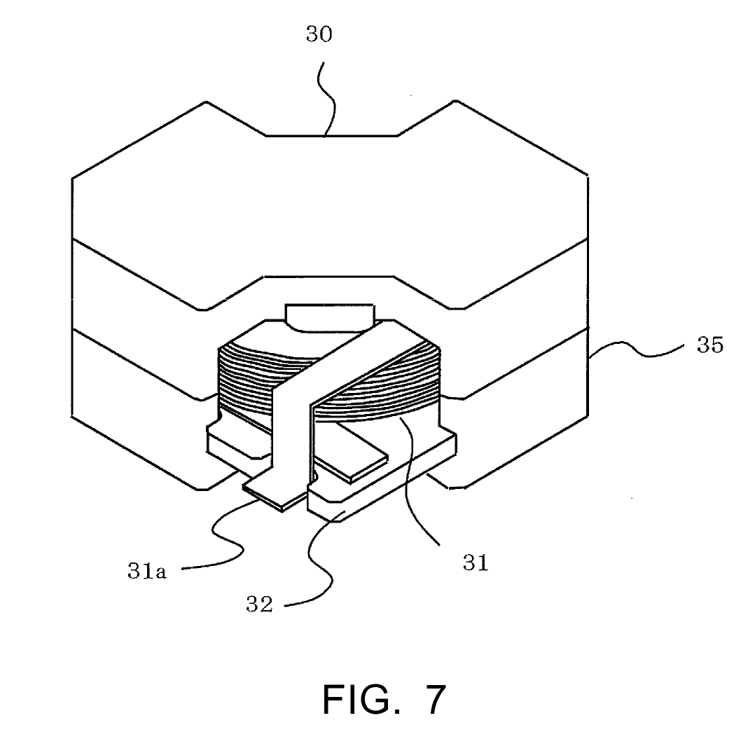

FIG. 7 is a perspective view of a choking coil to be mounted on the substrate according to the invention;

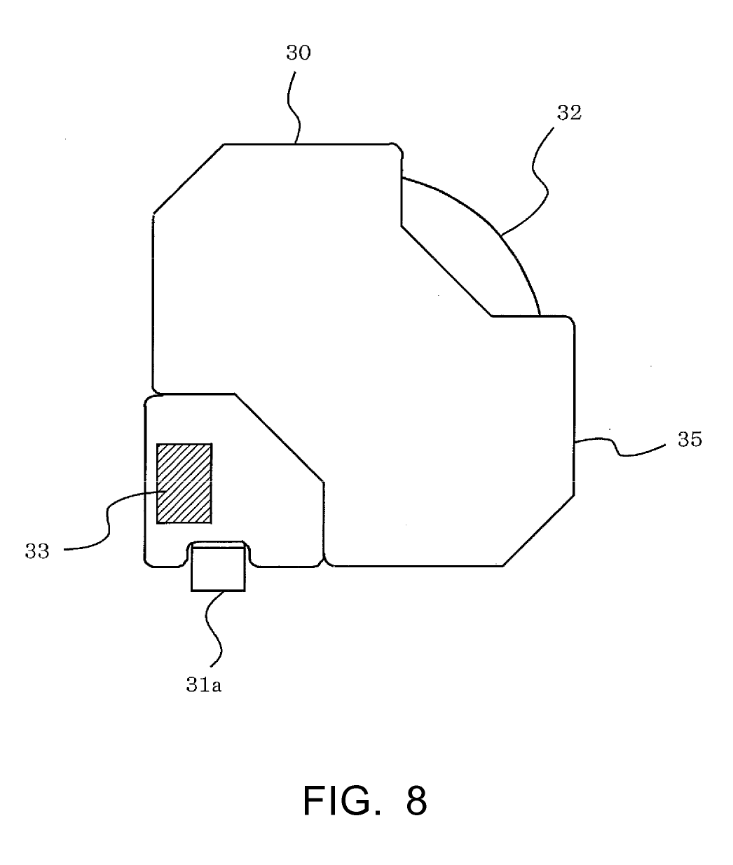

FIG. 8 is a drawing showing positions of the terminals when viewing the choking coil from the backside;

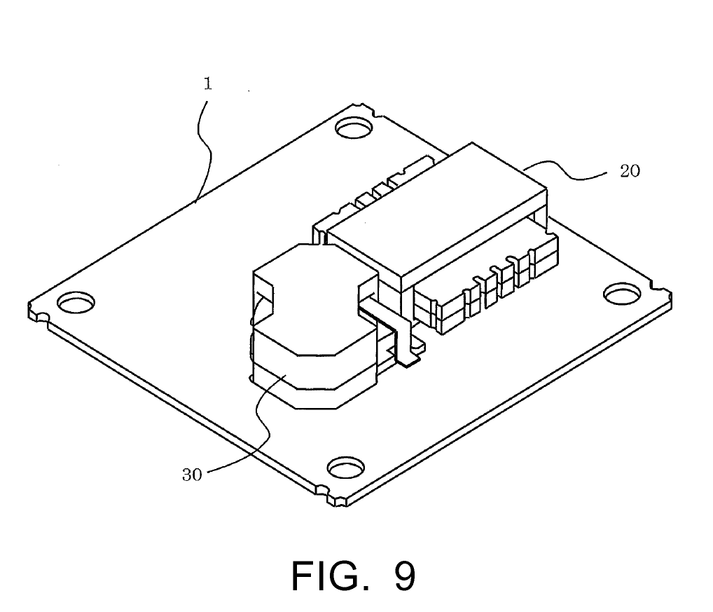

FIG. 9 is a perspective view of a front surface of the substrate including the planer transformer and the choking coil mounted thereon;

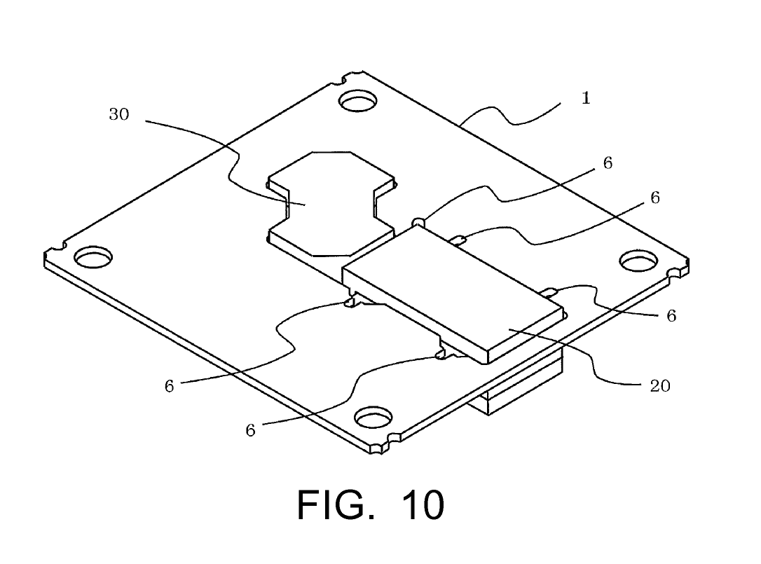

FIG. 10 is a perspective view of aback surface of the substrate including the planer transformer and the choking coil mounted thereon;

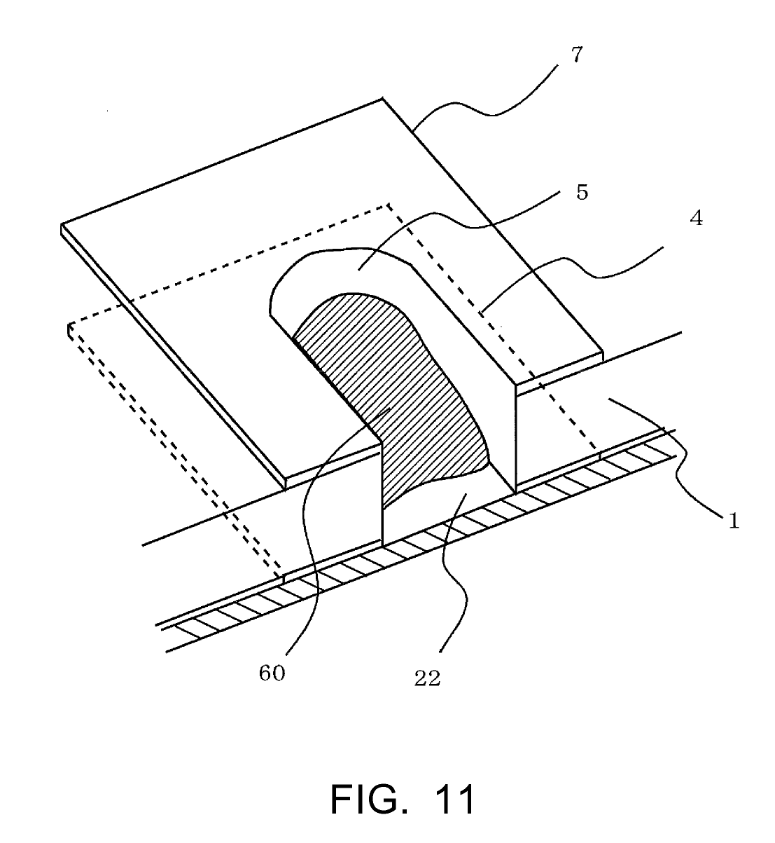

FIG. 11 is a perspective view showing a state of solder joint of the land on the substrate according to the invention;

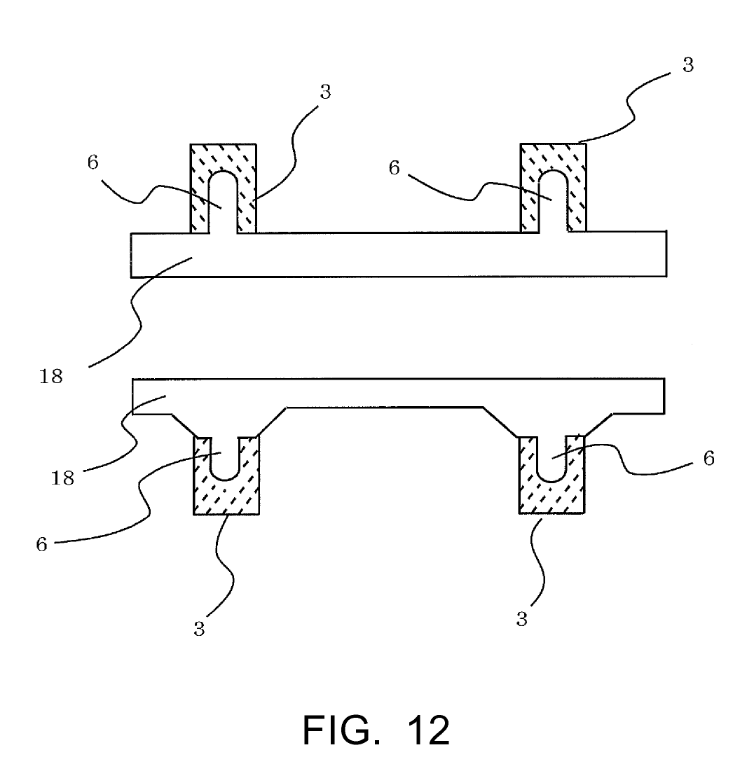

FIG. 12 is a drawing showing the front surface of the substrate for mounting a planer transformer or the like having terminals on a lower portion of a main body;

FIG. 13A is a plan view of a transformer mounted on a substrate showing a state of solder joint between terminals of the transformer and lands on the substrate; and

FIG. 13B is a front view of the transformer mounted on the substrate, also showing the state of solder joint between the terminals of the transformer and the lands on the substrate.

### DESCRIPTION OF PREFERRED EMBODIMENT

Referring now to the drawings, embodiments for implementing a substrate according to the invention will be described. The substrate according to the invention is a substrate for mounting a component having a planar terminal and is configured to ensure solder joint between the terminal of the component to be mounted and a land on the substrate by performing soldering in a state in which part of the terminal of the component is exposed on the land of the substrate by notching part of the land in the direction away from an end surface of the substrate. Therefore, the invention is applicable as a method of mounting any components irrespective of the types such as electronic, electric, etc. as long as they have a planer terminal.

FIG. 1 is a drawing showing a front surface of a substrate according to the invention, FIG. 2 is a drawing showing a back surface of the substrate according to the invention, FIG. 3 is an enlarged perspective view of a land on the substrate according to the invention. In FIG. 1 and FIG. 2, wiring patterns provided on the substrate are omitted, and only parts of mounting patterns and through holes for mounting electronic components or the like necessary for description are shown.

As shown in FIG. 1 and FIG. 2, a substrate 1 is formed of a glass epoxy resin or the like as an insulating member, and has a thickness which provides a required strength of the substrate considering the weight and the like of electronic components to be mounted. The substrate 1 includes wiring patterns (not shown), circular holes 12, through holes 10, a space 14, and lands 3 on a front surface and a back surface thereof. The wiring patterns are wiring for connecting terminals of the components to be mounted thereon. The circular holes 12 are used for fixing fixtures on the substrate 1, so that another substrate or the like is mounted above the substrate 1 via the fixtures. The through holes 10 are holes penetrating through the front surface and the back surface, and the interiors of the holes are applied with a conductive plating material or the like for achieving connection between the front surface and the back surface.

The space 14 provided in the substrate 1 is used for mounting components to be mounted in a state of penetrating partly through the substrate 1. The lands 3 of the substrate 1 are parts to be connected to terminals of the components, and are used for connecting and fixing the terminals of the components by soldering. The space 14 shown in FIG. 1 and FIG. 2 are used for mounting a planer transformer and a choking coil described later on the substrate 1.

The lands 3 shown with hatching in FIG. 1 are patterns for mounting electric components and the like on the front surface of the substrate 1, and for joining the terminals of the electronic components and the like by soldering. In general, the term “land” indicates a pattern for mounting electronic components or the like on the front surface of the substrate. However, the land 3 on the substrate 1 according to the invention has a configuration described below. Therefore, a general land for the surface mounting is referred to as a mounting pattern 15.

As shown in FIG. 3, the land 3 of the substrate 1 in the invention includes a notch 6 formed by notching part of the land 3 in the direction away from an end surface of the substrate 1 which defines the space 14, and includes a first land 4 shown with hatching provided on the front surface and configured to be joined with a terminal of a component, and a second land 5 shown with hatching provided on an end portion of the notch 6. The second land 5 is plated with a conductive member, and is in a conducting state with the first land 4. The notch 6 is continued from the space 14.

As shown in FIG. 3, the shape of the second land 5 is a substantially elongated hole in plan view, and the shape of the second land 5 may be a semi-circular shape, a semi-elliptical shape (oval), and a triangular arc instead of a substantially elongated hole. The second land 5 includes the notch 6 which extends in parallel in the direction away from the end surface of the substrate 1 which defines the space 14 or is gradually narrowed. The size of the notch 6 may be determined by the size or the like of the terminal of the component to be mounted. The width of the notch 6 viewed from the end surface of the substrate is preferably 1.5 mm or larger. In this manner, the land 3 of the substrate 1 in the invention includes the first land 4 formed two-dimensionally on a plane of the substrate land the second land 5 formed in the direction of thickness of the substrate 1, and formed three-dimensionally on the substrate 1. Accordingly, since the surface area of the portion for solder joint between the terminal of the electronic component and the land on the substrate can be increased and the amount of solder to be used for joint can be increased, the land allows passage of a large current therethrough, and hence is suitable for mounting power conversion components such as a planer transformer.

A land 53 in the related art (shown in FIGS. 13A and 13B) is formed on a front surface or a back surface of the substrate in a substantially rectangular shape, a substantially square shape, or a substantially circular shape and is formed two-dimensionally on a plane of the substrate.

As shown in FIG. 2, the substrate 1 may be provided with patterns 7 formed in a conducting state with the second land 5 on the surface opposite from the front surface having the first land 4 to be joined with the terminal of the component. With the provision of the conductive patterns 7 on the surface opposite from the surface for mounting the component via the notch 6, heat from the terminal of the component is also transferred to the conductive patterns 7. Therefore, the patterns 7 also function as a heat-radiating pattern.

In the related art, an electric current or a signal of the land on the front surface of the substrate is caused to flow to the pattern on the back surface via the through hole 10. However, when passing a large current therethrough, a number of through holes are formed because the allowable current of a single through hole is too small. The through hole is also insufficient in terms of a heat conducting property, which is a property to conduct the heat of the land on the front surface of the substrate to the pattern on the back surface.

In this manner, the substrate according to the invention allows soldering in a state in which part of the terminal of the electronic component or the like is exposed on the land of the substrate by notching part of the land in the direction away from the end surface of the substrate, so that the solder joint between the terminal of the component to be mounted and the land on the substrate is ensured.

The substrate in the invention is provided with the notch by notching the part of the land in the direction away from the end surface of the substrate. Accordingly, the terminal of the planer transformer is visible when mounting a standardized surface-mounting planer transformer or the like. Therefore, the substrate of the invention supports the mounting of the power conversion components such as various planer transformers having a planar terminal.

[Method of forming Notch on Substrate]

Subsequently, a method of forming the notch 6 on the substrate according to the invention will be described with reference to FIG. 1 and FIG. 2. The substrate 1 shown in FIG. 1 and FIG. 2 employs an epoxy resin substrate fabricated by impregnating a glass fiber cloth as an insulating member with epoxy resin and molding the same and attaching copper foils on both surfaces thereof. First of all, formation of a circuit pattern is performed for forming circuit wiring on both surfaces of the substrate 1. The circuit patterns are formed on the both surfaces of the substrate 1 by transferring wiring pattern portions by photoresist, and then performing etching. Subsequently, punching for forming the through holes 10 for connecting the circuits on the front surface and the back surface of the substrate 1 is performed. At this time, punching for forming the notches 6 of the land is also performed simultaneously with the punching for forming the through holes 10. Formation of the space 14 for allowing insertion of the component bodies or the like on the substrate is not performed in the process of the punching.

Formation of the notches 6 on the lands 3 are achieved by punching parts of the land 3 to be notched on the side of the space 14 corresponding to the positions of the lands 3. For example, when the shape of the notch 6 is a semi-circular shape, punching of a circular shape is performed by placing a center of the circle on an outline of the space 14 to be formed in the substrate 1.

The space 14 to be provided in the substrate 1 is used for mounting part of the component body so as to penetrate through the substrate 1 or for providing openings at extremities of the notches 6. It is also possible to form the notches 6 in a shape other than the semi-circular shape.

Then, metal plating using a conductive member is performed to form a conductive plating on an inner wall of the circle. Subsequent to the metal plating, in order to form the space 14 or an opening 18 (shown in FIG. 12) in the substrate 1, the space 14 or openings are punched along the outer peripheries thereof by a punching machine or the like so as to remain the semi-circles which are positioned on the side of the lands 3 and are already punched. By punching the space 14 or the openings along the outer peripheries thereof, the semi-circular notches 6 formed by notching parts of the lands 3 in the direction away from the end surface of the substrate 1 which defines the space 14 or the openings are obtained.

Subsequently, parts other than the lands 3 to be subjected to the solder joint are applied with processing for protecting the surface by solder resist or the like. It is also possible to perform processing for facilitating the solder joint as needed.

Accordingly, since the interior of the circle which defines part of the notch 6 is also plated simultaneously with the plating of the through holes 10, the number of process steps can be reduced in comparison with the case where the end surface of the notch 6 is separately plated. It is also possible to perform the plating only the end surfaces of the notches 6 after the formation of the space 14 on the substrate in a separate step. The substrate in the invention employs the double-side substrate having the copper foils on both surfaces thereof. However, a multiple-layer substrate may be used depending on the type and the number of components to be mounted and complexity of the wiring pattern.

In this manner, the formation of the notches 6 in the substrate is not much different from the step of manufacturing substrates in the related art, and hence the cost of manufacturing the substrate can be kept down. There are disclosed various methods of manufacturing the substrate and the method of manufacturing the substrate in the invention is not limited to the manufacturing method described above.

### [Outline of Transformer to be Mounted]

Referring now to FIGS. 4 to 6, a planer transformer to be mounted on the substrate will be described. FIG. 4 is a perspective view of a planer transformer to be mounted on the substrate according to the invention, FIG. 5 is a development elevation of the planer transformer, and FIG. 6 is a drawing showing positions of terminals when viewing the planer transformer from the back side.

As shown in FIG. 4 and FIG. 5, a planar transformer 20 includes coil substrate members 21 each made up of multiple layers and having a coil formed by a pattern and a ferrite core 25 as a magnetic circuit. The coil substrate member 21 is made up of laminated substrates formed of an insulating material, and each of the substrates includes coils formed of an electric conductor such as a copper foil or the like on upper and lower surfaces thereof. The coils formed on the coil substrate member 21 each has a primary side which corresponds to an input of the transformer and a secondary side which corresponds to an output of the transformer. The each coil has a required number of turns. The coil substrate member 21 is formed with circular through holes 21a for allowing the ferrite core 25 so as to penetrate therethrough.

Provided on an end surface of the coil substrate member 21 are semi-circular through holes 21b for connecting between the primary side and the secondary side, and between the patterns of the coils on the respective coil substrate members 21. The coil substrate members 21 positioned on the upper side and the lower side are subjected to the soldering at the semi-circular through holes 21b provided on the end surfaces thereof, so that connection of the patterns of the coils between the respective coil substrate members 21 is achieved.

Provided on a bottom portion of the coil substrate member 21 on the side coming into contact with the substrate are planer terminals 22 shown with hatching on the primary side and the secondary side as shown in FIG. 6. The planar terminals 22 provided on the coil substrate member 21 are connected to the semi-circular through holes 21b on the primary side or the secondary side of the end surface of the coil substrate member 21 via the wiring pattern. A required number of the coil substrate members 21 are laminated and are used as the primary side and secondary side coils. The planar transformer 20 shown in FIG. 4 includes two of the coil substrate members 21 laminated one on top of another.

As shown in FIG. 5, the ferrite core 25 is configured to form a magnet circuit of the planar transformer 20, and includes a bottom portion formed integrally into an E-shape and an upper portion formed into a flat-panel shape. The bottom portion formed into an E-shape includes a column-shaped center leg 25a for allowing fitting the coil substrate members 21 thereon for lamination at a center thereof and parallelepiped end portions 25b at both ends thereof.

The planar transformer 20 is manufactured by allowing penetration of the center leg 25a of the ferrite core 25 through the through holes 21a of a required number of the coil substrate members 21, aligning the flat-panel shaped upper portion with an upper surface of the bottom portion of the ferrite core 25 and fixing the same. Subsequently, the through holes provided at the end portions 25b of the coil substrate members 21 are subjected to soldering as needed to complete the planar transformer 20.

As shown in FIG. 4, in the planar transformer 20, parts of the coil substrate members 21 extend from both side surfaces of the ferrite core 25. The bottom portion of the ferrite core 25 of the planar transformer 20 is inserted into the space 14 formed in the substrate, so that the planar transformer 20 is mounted on the substrate in a state in which extending portions of the bottom portion of the lowermost coil substrate member 21 are in contact with the substrate.

### [Outline of Choking Coil to be Mounted]

Subsequently, referring now to FIGS. 7 to 8, a choking coil to be mounted on the substrate will be described. FIG. 7 is a perspective view of a choking coil to be mounted on the substrate according to the invention and FIG. 8 is a drawing showing the position of the terminal when viewing the choking coil viewed from the back side.

As shown in FIG. 7, the choking coil includes an edgewise coil 31 formed into a spring shape, a fixing substrate 32 configured to support the edgewise coil 31 and having a terminal 33 to which a starting point of the edgewise coil 31 is electrically connected, and a pair of cores 35 formed of ferrite or the like for forming a magnetic circuit. The edgewise coil 31 includes a column-shaped center leg (not shown) at a center of the core 35, and the coil is inserted onto the center leg. The starting point of the edgewise coil 31 is subjected to solder joint to the land on the fixing substrate 32 and is electrically connected to the terminal 33 via the interior of the fixing substrate 32. An end point of the edgewise coil 31 extends from an upper portion of the edgewise coil 31 and is formed into an L-shape, and is configured to be subjected to direct solder joint to the mounting pattern 15 (shown in FIG. 1) on the substrate.

The fixing substrate 32 has a doughnut shape, has the edgewise coil 31 on an upper surface thereof fixed with an adhesive agent or the like, and is stored on the bottom portion of the core 35. The fixing substrate 32 is formed with a land, and the starting point of the edgewise coil 31 is connected thereto. As shown with hatching in FIG. 8, the planer terminal 33 for input is provided on a back surface of the fixing substrate 32 via a through hole of the land. A side surface of the choking coil 30 is opened between the outer lags of the core 35 (not shown), and part of the fixing substrate 32 is exposed from the side surface of the core 35. The bottom portion of the core 35 of the choking coil 30 is inserted into the space 14 formed in the substrate, so that the choking coil 30 is mounted on the substrate in a state in which the portion of the fixing substrate 32 exposed from the side surface of the core 35 is in contact with the substrate.

In this manner, one end of the edgewise coil 31 of the choking coil 30 is subjected to solder joint to the land of the fixing substrate 32, and the land of the fixing substrate 32 is electrically connected to the planer terminal 33 via the through hole in the interior of the fixing substrate 32. A connecting end 31a as the other end of the edgewise coil 31 is formed into an L-shape and is subjected to direct solder joint to the mounting pattern 15 of the substrate.

### [Mounting of Component on Substrate]

Subsequently, mounting of the planar transformer 20 and the choking coil 30 using the substrate 1 having the above-described notches 6 will be described with reference to FIGS. 9 to 11. FIG. 9 is a perspective view of a front surface of the substrate having the planer transformer and the choking coil mounted thereon, FIG. 10 is a perspective view of a back surface of the substrate having the planer transformer and the choking coil mounted thereon, and FIG. 11 is a cross-sectional view showing a state of solder joint at the land on the substrate in the invention.

As shown in FIG. 9, the planar transformer 20 is inserted into the space 14 of the substrate 1, and the bottom portions of the coil substrate member 21 extending from both ends of the body of the planar transformer 20 come into contact with the front surface of the substrate 1. When mounting the planar transformer 20 onto the substrate 1, the terminals 22 of the planar transformer 20 are soldered in advance. Also, solder paste such as solder cream or the like is applied on the land 3 of the substrate 1 in advance. This is for improving soldering performance. Subsequently, the planar transformer 20 is inserted into the space 14 of the substrate 1, and the terminals 22 of the planar transformer 20 and the lands 3 of the substrate 1 are aligned to position the terminals 22 of the planar transformer 20 at predetermined positions with respect to the lands 3 of the substrate 1. Then, reflow soldering is performed. Solder joint between the terminals 22 of the planar transformer 20 and the first lands 4 on the front surface of the substrate 1 is performed, and solder joint between end surfaces of the notches 6 of the second lands 5 and the terminals 22 of the planar transformer 20 is also performed. The solder joint between the end surfaces of the notches 6 and the terminals 22 of the planar transformer 20 may be performed while melting the solder with a soldering iron or the like at the notches 6 of the lands on the substrate 1 from the back surface of the substrate 1 shown in FIG. 10. FIG. 11 is a perspective view showing a state of solder joint at the land viewed from the back surface of the substrate. As shown in FIG. 11, the solder joint is performed so as to form a gentle inclination from an arc of the end surface of the notch 6 to the terminals 22 of the planar transformer 20. In this manner, the terminals 22 of the planar transformer 20 are subjected to the solder joint by the first lands 4 and the second lands 5.

When mounting the choking coil 30 to the substrate 1, the terminal 33 of the fixing substrate 32 is soldered in advance. Also, solder paste such as solder cream or the like is applied on the land 3 of the substrate 1 in advance. This is for improving soldering performance. Subsequently, the choking coil 30 is inserted into a predetermined position of the space 14 of the substrate 1, so that parts of the fixing substrate 32 positioned on both ends of the core 35 come into contact with the front surface of the substrate 1. The terminal 33 of the fixing substrate 32 and the land of the substrate 1 are aligned so that the terminal 33 of the fixing substrate 32 is positioned at a predetermined position with respect to the land 3 of the substrate 1.

Then, reflow soldering is performed. Solder joint of the L-shaped connecting end 31a (FIGS. 7 and 8) of the edgewise coil 31 and the mounting pattern 15 (FIG. 1) is performed on the front surface of the substrate 1, and solder joint between the terminal 33 (FIG. 8) of the fixing substrate 32 and the land 3 (FIG. 1) on the substrate 1 is performed. The solder joint between the end surfaces of the notches 6 and the terminal 33 of the fixing substrate 32 may be performed while melting the solder with a soldering iron or the like at the notches 6 of the lands on the substrate 1 from the back surface of the substrate 1 shown in FIG. 10.

In this manner, when mounting the planar transformer 20 onto the substrate, since the terminals 22 of the planar transformer 20 is exposed and hence is visible on the lands 3 of the substrate 1, solder joint between the second lands made up of the end surfaces of the notches 6 and the terminals 22 of the planar transformer 20 can be performed while melting solder onto the notches 6 of the lands 3 on the substrate 1 with the soldering iron or the like, solder joint can be performed reliably. Solder joint of the choking coil can also be performed reliably. In addition, the height of the planer transformer and the choking coil from the front surface of the substrate can be kept low by mounting the bottom portions of the planer transformer and the choking coil by inserting the same into the space of the substrate.

As described thus far, the substrate according to the invention allows soldering in a state in which part of the terminal of the electronic component or the like is exposed on the land of the substrate by notching part of the land in the direction away from the end surface of the substrate, so that the solder joint between the terminal of the component to be mounted and the land on the substrate is ensured.

Also, with the provision of the notches 6 on the lands 3, the terminals on the lower surface of the member extending from the side surface is exposed on the land of the substrate, and hence is visible, so that reliable solder joint between the terminals of the components and the lands of the substrate is achieved.

In particular, when performing solder joint by inserting an extremity of the soldering iron into the notch, part of the terminal of the component is visible using penetration of the notch, so that accurate soldering can be performed while confirming the state of the solder joint.

Since the lands of the substrate of the invention is made up of the lands provided on the substrate and the end surfaces of the notches in the direction of the thickness of the substrate, the surface area of the solder joint portion between the terminals of the electronic components or the like and the lands of the substrate can be increased, and the amount of solder used for joint can be increased. Accordingly, the lands of the substrate of the invention allow passage of a large current, and hence are suitable for mounting the power conversion components such as a transformer.

Since the substrate of the invention is provided with the notches on the lands, touch up (addition and mending of solder) after the mount of the components can be performed easily via the notches 6.

The substrate of the invention is provided with the provision of the conductive patterns 7 on the surface opposite from the surface for mounting the component via the notch 6, and hence heat from the terminal of the component is also transferred to the conductive patterns 7. Therefore, the patterns 7 also functions as a heat-radiating pattern.

The substrate according to the invention includes the space 14 penetrating therethrough for insertion of parts of the component bodies on the substrate, and the notches formed by notching parts of the lands in the direction away from the end surface defining the space of the substrate.

Therefore, it is suitable for mounting the component having a terminal on the lower surface of the member extending from the side surface. In other words, since the component is mounted into the space provided in the substrate in a state in which part of the component is penetrated through the substrate, the height of the component from the front surface of the substrate can be kept low. Also, with the provision of the notches on the lands, the terminals on the lower surface of the member extending from the side surface is exposed on the land of the substrate, and hence is visible, so that reliable solder joint between the terminals of the components and the lands of the substrate is achieved.

The planer transformer in the related art is required to form a terminal for mounting the same separately on the substrate, or to prepare a specific terminal base, and hence has a special terminal. Therefore, the substrates are required to have forms corresponding to the forms of the terminals on the respective planer transformers. The substrate of the invention is suitable for mounting the standardized surface-mounting planer transformer, and hence supports the mounting of the power conversion components such as various planer transformers having a planar terminal.

Also, the steps of manufacturing the substrates in the invention is not much different from those in the related art, and hence the cost of manufacturing the substrate can be kept down.

### EXAMPLES

The mode of mounting in which part of the planer transformer is embedded into the space provided in the substrate has been descried thus far. Subsequently, a substrate configured to mount a transformer or the like having a terminal on a lower portion of a main body as shown in FIG. 13 on the front surface thereof will be described with reference to FIG. 12. FIG. 12 is a drawing showing the front surface of the substrate for mounting a planer transformer or the like having terminals on the lower portion of the main body on the front surface thereof. As shown in FIG. 12, the substrate includes the openings 18, and part of the lands 3 shown with hatching is notched in the direction away from the end surfaces of the openings 18, so that the notches 6 are formed on the lands 3. The openings 18 and the notches 6 on the lands 3 communicate with each other. The openings 18 provided on the substrate each have a shape such as rectangular shape, square shape, or trapezoidal shape in plan view.

The substrate shown in FIG. 1 has the space on the substrate for embedding and mounting part of the planer transformer or the like, and includes the notches formed by notching parts of the lands in the direction away from the end surface of the substrate which defines the space. In contrast, the substrate shown in FIG. 12 has openings 18 on the side of the end surfaces of the notches 6 of the lands 3. The openings 18 are not for embedding parts of the mounting component, but for preventing defecting soldering caused by air bubbles in the notches and also for facilitating the confirmation of the state of the solder joint. The lands 3 of the substrate shown in FIG. 12 have the same configuration as the lands 3 shown in FIG. 3.

Mounting of the planer transformer onto the substrate is performed by aligning the terminals formed into a planer shape provided in the periphery of the lower surface of the planer transformer with the lands 3 of the substrate, and performing solder joint at the notches from the back surface of the substrate. Accordingly, the substrate according to the invention allows soldering in a state in which part of the terminal of the component to be mounted is exposed on the land of the substrate, so that the solder joint between the terminal of the component to be mounted and the land on the substrate is ensured.

The openings 18 may be provided for each of the notches 6. It is also possible to provide only the notches 6 without providing the openings 18. However, defective soldering may occur due to the air bubbles in the notches with the provision only of the notches 6. In addition, time may be consumed for the solder joint work, and confirmation of the state of solder joint may become difficult. Therefore, it is preferable to provide the openings which communicate with the notches.

### REFERENCE NUMERAL

1 substrate
3,53 land
4 the first land
5 the second land
6 notch
7 pattern
10 three hole
12 circular hole
14 space
15 mounting pattern
18 opening
20 planar transformer
21 coil substrate member
21a through hole
21b semi-circular through hole
22,33,51 terminal
25 ferrite core
25a center leg
25b end portion
30 choking coil
31 edge wise coil
31a connecting end
32 fixing substrate
35 core
50 transformer
60 solder

1. A substrate configured to mount a component having a planer terminal comprising:
a land subjected to solder joint with respect to the terminal of the component,
wherein at least part of the land is notched in a direction away from an end surface of the substrate.

2. The substrate according to claim 1, comprising:
a space penetrating through the substrate; and
a notched portion formed by notching the part of the land in the direction away from the end surface of the substrate which defines the space.

3. The substrate according to claim 2, wherein the end surface of the notch is plated with a conductive material, and is formed so as to be in a state of conducting with the land on the substrate.

4. The substrate according to claim 2, wherein the land on the substrate is formed so that part of the terminal of the component is positioned right above the notch.

5. The substrate according to claim 3, wherein the land on the substrate is formed so that part of the terminal of the component is positioned right above the notch.

6. The substrate according to claim 2, wherein the land on the substrate is made up of the land provided on the substrate and the end surface of the notch in the direction of the thickness of the substrate.

7. The substrate according to claim 3, wherein the land on the substrate is made up of the land provided on the substrate and the end surface of the notch in the direction of the thickness of the substrate.

8. The substrate according to claim 4, wherein the land on the substrate is made up of the land provided on the substrate and the end surface of the notch in the direction of the thickness of the substrate.

9. The substrate according to claim 5, wherein the land on the substrate is made up of the land provided on the substrate and the end surface of the notch in the direction of the thickness of the substrate.

10. The substrate according to claim 2, wherein a conductive pattern is provided on a surface opposite from a surface for mounting the component via the notch.

11. The substrate according to claim 3, wherein a conductive pattern is provided on a surface opposite from a surface for mounting the component via the notch.

12. The substrate according to claim 4, wherein a conductive pattern is provided on a surface opposite from a surface for mounting the component via the notch.

13. The substrate according to claim 5, wherein a conductive pattern is provided on a surface opposite from a surface for mounting the component via the notch.

14. The substrate according to claim 6, wherein a conductive pattern is provided on a surface opposite from a surface for mounting the component via the notch.

15. The substrate according to claim 7, wherein a conductive pattern is provided on a surface opposite from a surface for mounting the component via the notch.

16. The substrate according to claim 8, wherein a conductive pattern is provided on a surface opposite from a surface for mounting the component via the notch.

17. The substrate according to claim 9, wherein a conductive pattern is provided on a surface opposite from a surface for mounting the component via the notch.
